(19) United States
(12) Patent Application Publication
(10) Pub. No.: US 2011/0249404 A1
(43) Pub. Date: Oct. 13, 2011

(54) MOUNTING APPARATUS AND MOUNTING ASSEMBLY FOR HEAT DISSIPATING COMPONENT

(75) Inventor: PO-WEN CHIU, Tu-Cheng (TW)

(73) Assignee: HON HAI PRECISION INDUSTRY CO., LTD., Tu-Cheng (TW)

(21) Appl. No.: 12/759,023

(22) Filed: Apr. 13, 2010

(51) Int. Cl. H05K 7/20

(52) U.S. Cl. 361/704

(57) ABSTRACT

A mounting apparatus includes a support, a first lever and a second lever. A first pair and a second pair of positioning portions are located on the support. A first hook portion and a second hook portion are located on the support and bent towards each other. The first and second levers are rotatably secured to the positioning portions. The first lever includes a first pressing portion located between the first pair of the positioning portions. The second lever includes a second pressing portion located between the second pair of the positioning portions. The first and second levers are disengaged from the first and second hook portions when in an unlocked position, and engaged with the first and second hook portions when in a locked position. The first and second pressing portions are capable of pressing retaining portions of a heat dissipating component.

### BACKGROUND

1. Technical Field

The present disclosure relates to a mounting apparatus and a mounting assembly for a heat dissipating component.

2. Description of Related Art

A conventional means for securing a heat sink to a motherboard by screws. This will result in inconvenient use of screwdrivers to secure the screws one by one into corresponding holes defined in the heat sink and the motherboard.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partly exploded view of a mounting apparatus and a printed circuit board in accordance with an embodiment.

FIG. 2 is an isometric view of an embodiment of a heat dissipating component.

FIG. 3 an exploded view of the mounting apparatus of FIG. 1.

FIG. 4 is another exploded view of the mounting apparatus of FIG. 1.

FIG. 5 is an assembled view of the mounting apparatus and the printed circuit board of FIG. 1.

FIG. 6 is an assembled view of the mounting apparatus and the printed circuit board of FIG. 5 and the heat dissipating component of FIG. 2, showing first and second levers in an unlocked position.

FIG. 7 is similar to FIG. 6, but showing the first and second levers in a locked position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

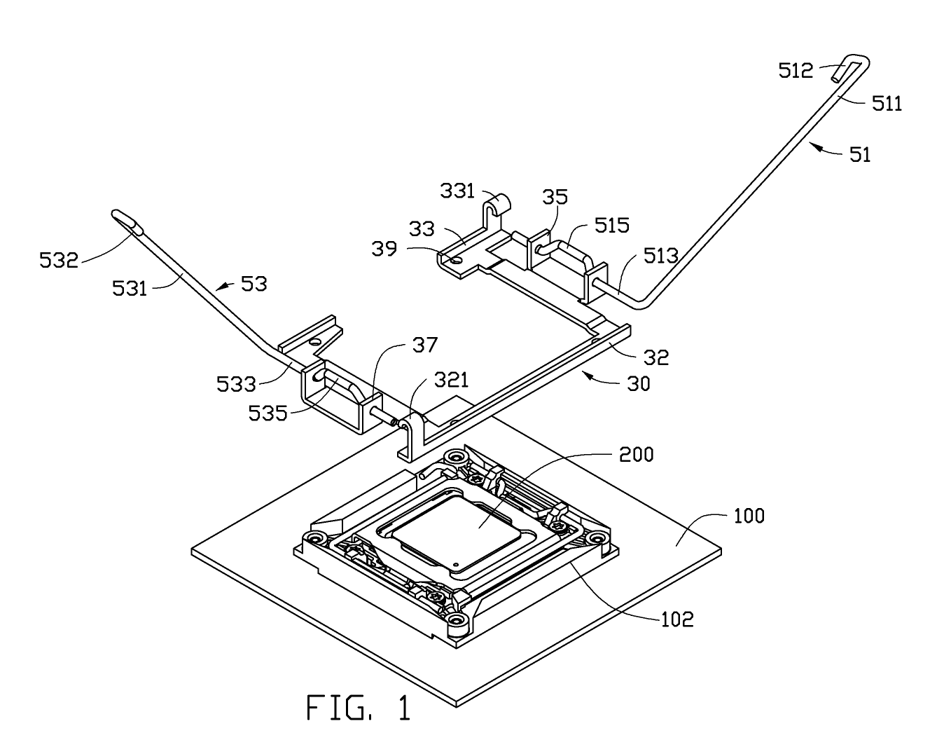

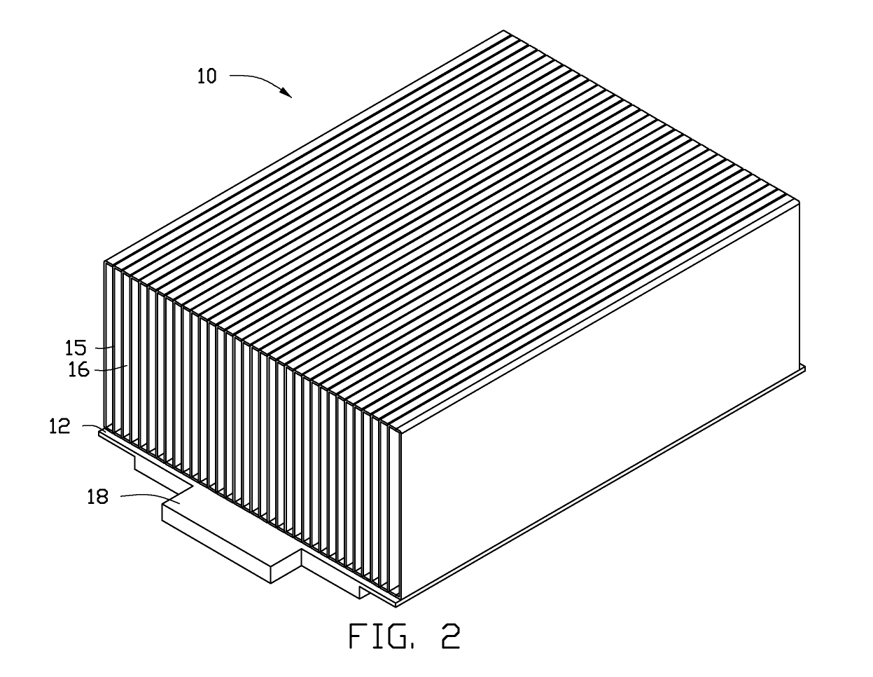

Referring to FIGS. 1-2, a mounting apparatus in accordance with an embodiment is configured for securing a heat dissipating component 10 to a printed circuit board 100, such as a motherboard. The printed circuit board 100 has a cup seat 102 configured for securing a CPU 200. The heat dissipating component 10 includes a base 12 and a fin portion 14 located on the base 12. The fin portion 14 includes a plurality of parallel fins 15 substantially perpendicular to the base 12, and a plurality of gaps 16 between adjacent two fins 15 are defined in the fin portions 14. Two retaining portions 18 (only one is shown in figures) are located on the heat dissipating component 10. In an embodiment, the retaining portions 18 are on two sides of the heat dissipating component 10. In another embodiment, the retaining portions 18 extend from the base 12 of the heat dissipating component 10, and the retaining portions 18 are disposed on sides facing the gaps 16.

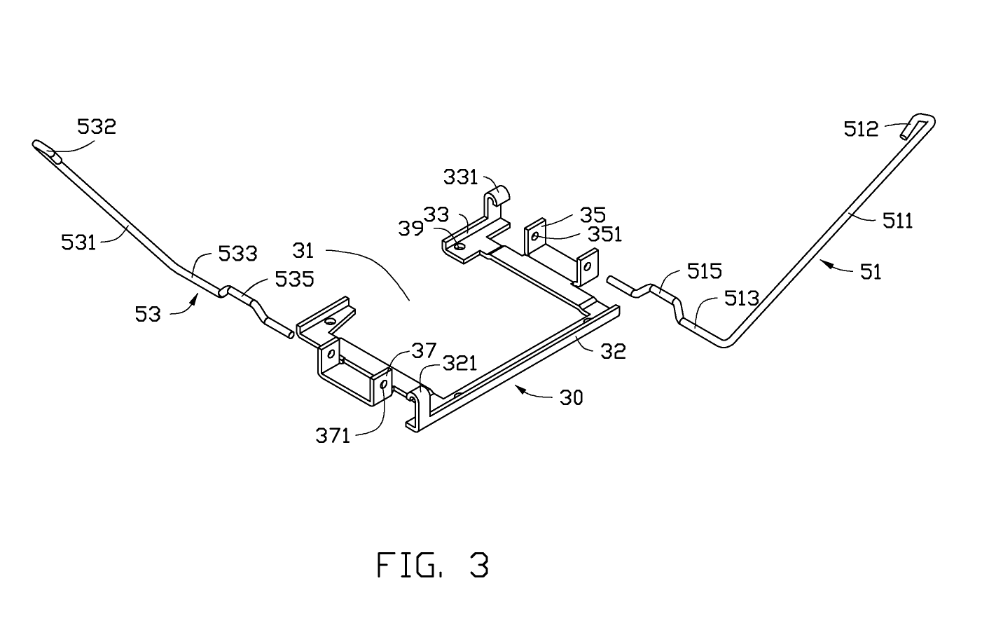

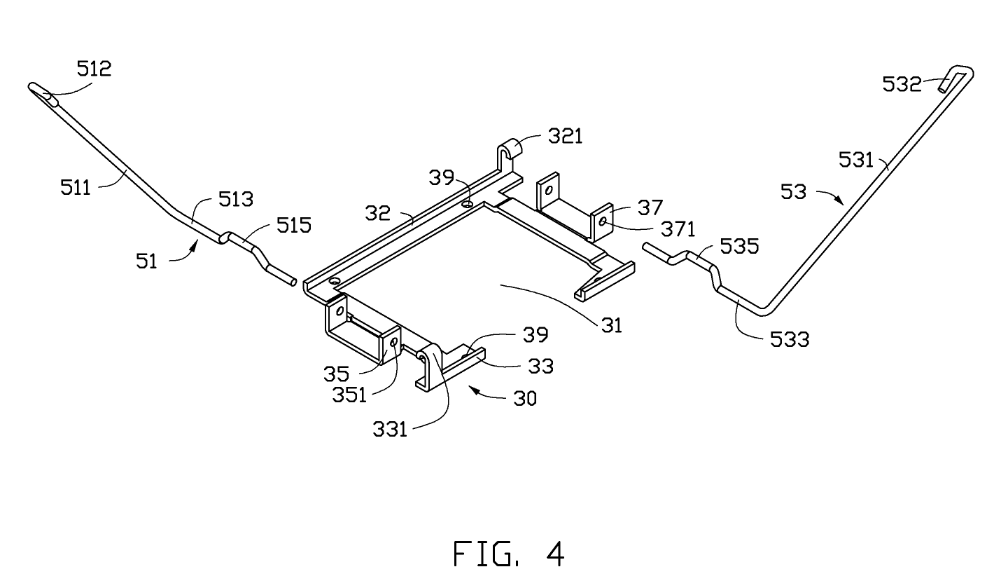

Referring to FIGS. 3-4, the mounting apparatus includes a support 30, a first lever 51, and a second lever 53.

The support 30 defines an opening 31 that is capable of having a CPU 200 and inserted therein. A first flange 32 and a second flange 33 are located on opposite sides of the support 30. A first hook portion 321 and a second hook portion 331 are located on the first and second hook portions 321, 331, respectively. In an embodiment, the first and second hook portions 321, 331 are cattycorner to each other. In another embodiment, the first and second hook portions 321, 331 extend respectively from the first and second flanges 32, 33 and are bent towards each other. A pair of first positioning portions 35 and a pair of second positioning portions 37 are located on another opposite sides of the support 30. In an embodiment, the sides where the first and second flanges 32, 33 are located opposite to the sides where the first and second positioning portions 35, 37 are located. In another embodiment, the first and second positioning portions 35, 37 are tabs bent from the support 30. Each of the first and second positioning portions 35, 37 defines first and second pivot holes 351, 371, respectively. In an embodiment, the first and second positioning portions 35, 37 are substantially parallel to the fins 15. A plurality of the through holes 39, defined in the support 30, and a plurality of fasteners (not shown), such as screws, are capable of being engaged in the through holes 39 to secure to the support 30 to the printed circuit board 100 or the CPU seat 102. In an embodiment, the support 30 is made of a sheet metal by punch.

The first lever 51 includes a first operating portion 511 and a first installing portion 513. The first operating portion 511 is configured to engage with the first hook portion 321. A first ear end 512 is disposed at a distal end of the first operating portion 511. The first installing portion 513 is configured to rotatably engage in the first pivot holes 351. A first pressing portion 515 is set on the first installing portion 513 and set at an angle from the first operating portion 511. In an embodiment, the first lever 51 is wire-shaped.

The second lever 53 generally has the same structure as the first lever 51, and includes a second operating portion 531 and a second installing portion 533. The second operating portion 531 is configured to engage with the second hook portion 331. A second ear end 532 is disposed at a distal end of the first operating portion 531. The second installing portion 533 is configured to rotatably engage in the second pivot holes 371. A second pressing portion 535 is set on the second installing portion 533 and set at an angle from the first operating portion 531. In an embodiment, the second lever 53 is wire-shaped.

Referring to FIG. 1, the first and second installing portions 513, 533 are engaged in the first and second pivot holes 351, 371 of the first and second positioning portions 35, 37, respectively. The first pressing portion 515 is positioned between the first positioning portions 35, and the second pressing portion 535 is positioned between the second positioning portions 37.

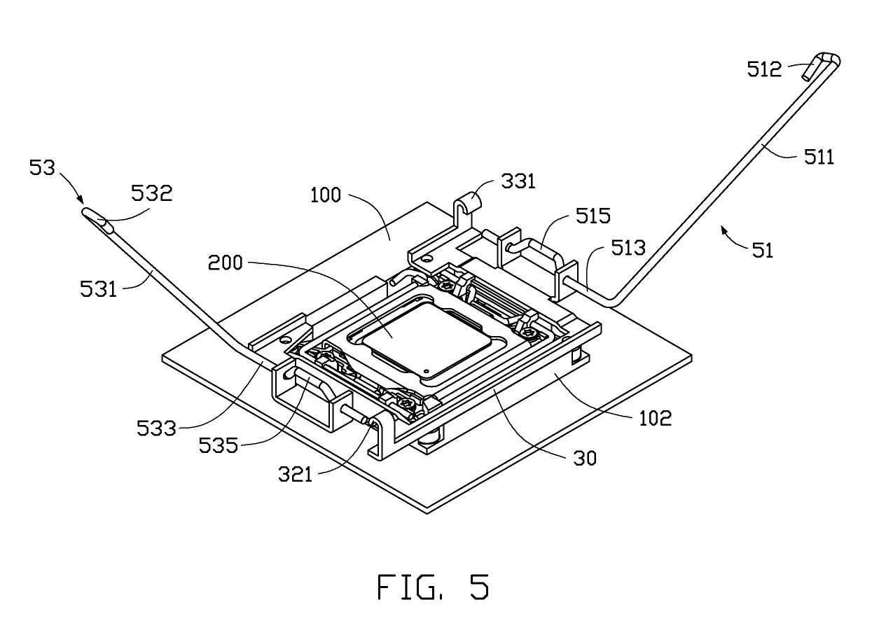

Referring to FIG. 5, the support 30, together with the first and second levers 51, 53, is secured to the printed circuit board 100. The first and second levers 51, 53 have an unlocked position, where the first and second levers 51, 53 are disengaged from the first and second hook portions 321, 331.

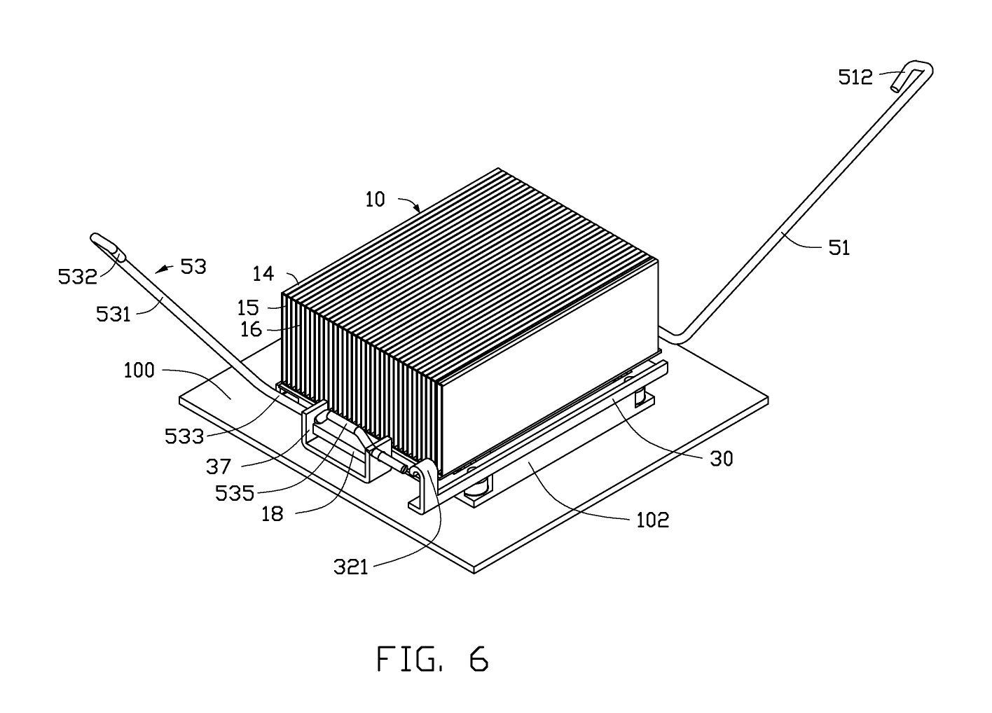

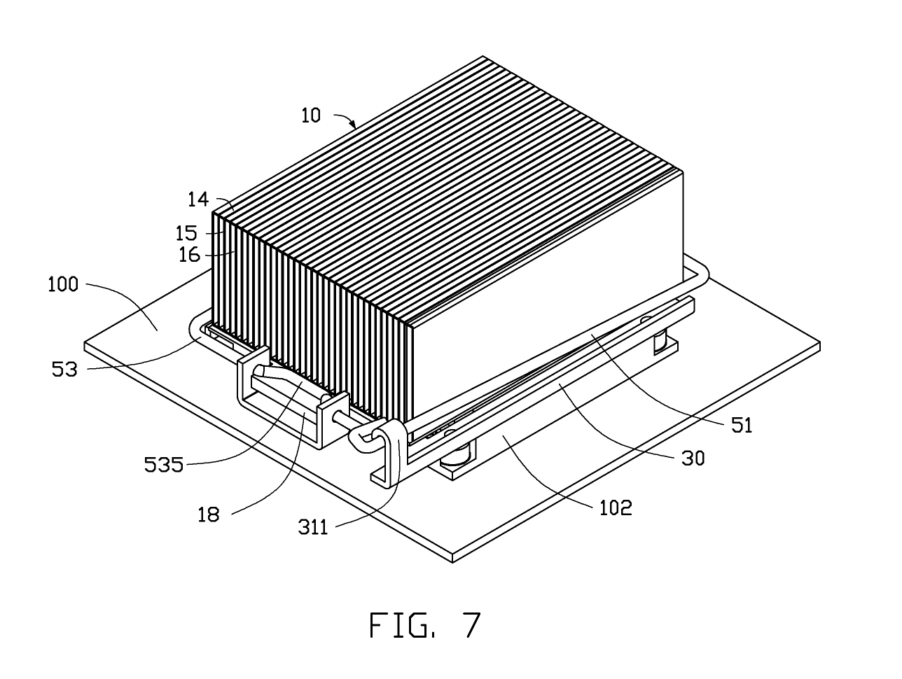

Referring also to FIGS. 6-7, the heat dissipating component 10 is placed on the support 30. The retaining portions 18 are adjacent to the first and second positioning portions 35, 37, respectively. In an embodiment, the base 12 abuts the support 30, one retaining portion 18 is positioned between the first retaining portions 35, and another retaining portion 18 is positioned between the second retaining portions 37. The first and second levers 51, 53 are rotated by operating the first and second ear ends 512, 532 of the first and second operating portions 511, 531. When the first and second retaining portions 35, 37 abut the retaining portions 18 of the heat dissipating component 10, the first and second operating portions 511, 531 are further operated to resiliently deform the first and second levers 51, 53 and engage with the first and second hook portions 321, 331 of the support 30, where the first and second levers 51, 53 are positioned in a locked position (shown in FIG. 7). Thus, the heat dissipating component 10 is secured to the printed circuit board 100 or the CPU seat 102.

In disassembly of the heat dissipating component 10, the first and second levers 51, 53 are operated by pushing the first and second ear end 512, 532 to disengage the first and second operating portions 511, 531 from the first and second hook portions 321, 331 and then rotated from the locked position to the second locked position. Therefore, the heat dissipating component 10 can be removed from the printed circuit board 100.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a support, a first pair and a second pair of positioning portions located on two opposite sides of the support, a first hook portion and a second hook portion are located on the support, the first and second hook portions being bent towards each other;
a first lever rotatably secured to the first pair of the positioning portions, the first lever comprises a first pressing portion located between the first pair of the positioning portions; and
a second lever rotatably secured to the second pair of the positioning portions, the second lever comprises a second pressing portion located between the second pair of the positioning portions;
wherein the first and second levers are rotatable between an unlocked position, where the first and second levers are disengaged from the first and second hook portions, and a locked position, where the first and second levers are engaged with the first and second hook portions; and the first and second pressing portions are capable of pressing retaining portions of a heat dissipating component.

2. The mounting apparatus of claim 1, wherein the first and second levers are wire-shaped.

3. The mounting apparatus of claim 1, wherein the support further comprises a first flange and a second flange; and the first and second hook portions extend respectively from the first and second flanges.

4. The mounting apparatus of claim 1, wherein the first hook portion is cattycorner to the second hook portion.

5. The mounting apparatus of claim 1, wherein the support defines an opening capable of having a CPU inserted therein.

6. The mounting apparatus of claim 1, wherein each of the first and second levers comprises an installing portion and an operating portion substantially perpendicular to the installing portion; the installing portions are rotatably engaged with the first and second pairs of positioning portions; and the operating portions are engaged with the first and second hook portions in the locked position.

7. The mounting apparatus of claim 6, wherein each positioning portion of the support defines a pivot hole; and diameters of the installing portions are less than the diameters of the pivot holes.

8. A mounting assembly comprising
a heat dissipating component, the heat dissipating component comprising a base and a plurality of parallel fins located on the base, two retaining portions extending from opposite sides of the base;
a support, a first pair and a second pair of positioning portions located on two opposite sides of the support, a first hook portion and a second hook portion located on the support, and each positioning portion being parallel to the fins;
a first lever rotatably secured to the first pair of the positioning portions, the first lever comprises a first pressing portion located between the first pair of the positioning portions; and
a second lever rotatably secured to the second pair of the positioning portions, the second lever comprises a second pressing portion located between the second pair of the positioning portions;
wherein the first and second levers are rotatable between an unlocked position, where the first and second levers are disengaged from the first and second hook portions, and a locked position, where the first and second levers are engaged with the first and second hook portions; and the first and second pressing portions are capable of pressing the retaining portions of the heat dissipating component in the locked position.

9. The mounting assembly of claim 8, wherein the first and second levers are wire-shaped.

10. The mounting assembly of claim 8, wherein the support further comprises a first flange and a second flange; and the first and second hook portions extend respectively from the first and second flanges.

11. The mounting assembly of claim 8, wherein the first and second hook portions are cattycorner to each other.

12. The mounting assembly of claim 8, wherein the support defines an opening capable of having a CPU inserted therethrough.

13. The mounting assembly of claim 8, wherein each of the first and second levers comprises an installing portion and an operating portion substantially perpendicular to the installing portion; the installing portions are rotatably engaged with the positioning portions; and the operating portions are engaged with the first and second hook portions in the locked position.

14. The mounting assembly of claim 13, wherein each positioning portion of the support defines a pivot hole; and diameters of the installing portions are less than the diameters of the pivot holes.

15. A mounting apparatus comprising:
a support, a first pair and second pair of positioning portions located on two opposite sides of the support, a first hook portion and a second hook portion located on the support;
a first lever rotatably secured to the first pair of the positioning portions, the first lever comprises a first pressing portion located between the first pair of the positioning portions; and
a second lever rotatably secured to the second pair of the positioning portions, the second lever comprises a second pressing portion located between the second pair of the positioning portions;
wherein one retaining portion of a heat dissipating component is positioned between the first pair of the positioning portions, and another retaining portion of the heat dissipating component is positioned between the second pair of the positioning portions;
the first and second levers are resiliently deformed to engage with the first and second hook portions to have the first and second pressing portion pressing the retaining portions.

16. The mounting apparatus of claim 15, wherein the first and second hook portions are cattycorner to each other.

17. The mounting apparatus of claim 15, wherein the support defines an opening capable of having a CPU inserted therein.

18. The mounting apparatus of claim 15, wherein each of the first and second levers comprises an installing portion and an operating portion substantially perpendicular to the installing portion; the installing portions are rotatably engaged with the first and second pairs of the positioning portions; and the operating portions are engaged with the first and second hook portions.

19. The mounting apparatus of claim 15, wherein the support is secured to a printed circuit board.

20. The mounting apparatus of claim 15, wherein the first pressing portion is set at an angle to the first operating portion; and the second pressing portion is set at an angle to the second operating portion.
